(19) United States
(12) Patent Application Publication
(10) Pub. No.: US 2013/0314861 A1
(43) Pub. Date: Nov. 28, 2013

(54) MULTI-POSITION SUPPORT FOR A PERSONAL ELECTRONIC DEVICE

(71) Applicant: John E. Burford, Austin, TX (US)

(72) Inventor: John E. Burford, Austin, TX (US)

(21) Appl. No.: 13/902,782

(22) Filed: May 25, 2013

Related U.S. Application Data
(60) Provisional application No. 61/652,196, filed on May 26, 2012.

(51) Int. Cl. H05K 7/00; F16M 13/00; B60N 3/00

(52) U.S. Cl. CPC H05K 7/00; B60N 3/004; F16M 13/00
USPC 361/679.01; 248/346.03; 248/309.1; 248/213.2; 297/163

(57) ABSTRACT

A support member includes a base, a first wall and an opposite second wall spaced apart from the first wall. The base, the first wall and the second wall define an elongated slot. The first wall extends from the base and includes a surface interior to the slot which includes a plurality of support lands. The second wall extends from the base and includes a plurality of apertures extending through the second wall in a direction transverse to the elongated slot.

### CROSS REFERENCE TO RELATED APPLICATIONS

The present invention is related to and claims priority to Provisional Application U.S. Ser. No. 61/652,196, filed on May 26, 2012.

### BACKGROUND

The present disclosure relates generally to support devices and more particularly to an apparatus and system for supporting a personal electronic device in multiple positions.

Some present personal electronic devices include built-in supports or holders; however, many such devices must be hand-held when in use. It would be of benefit to provide a holder member, which supports such devices in more than one position for hands-free use.

### SUMMARY

One embodiment, accordingly, includes an apparatus which includes a base, a first wall and an opposite second wall spaced apart from the first wall. The base, the first wall and the second wall define an elongated slot. The first wall extends from the base and includes a surface interior to the slot which includes a plurality of support lands. The second wall extends from the base and includes a plurality of apertures extending through the second wall in a direction transverse to the elongated slot.

### BRIEF DESCRIPTION OF THE DRAWINGS

FIG. 1 is an end view illustrating an embodiment of a profile of a holder.

FIG. 2 is a perspective view illustrating an embodiment of the holder of FIG. 1.

FIG. 3 is a perspective view illustrating an embodiment of the holder of FIG. 1.

FIGS. 4, 5 and 6 are end views diagrammatically illustrating an embodiment of the holder of FIG. 1 supporting a personal electronic device in multiple positions.

FIG. 7 is a perspective view illustrating an embodiment of the holder of FIG. 1, mounted on a foldable tray device.

FIG. 8 is a side elevational view of an airline seat and seat-back tray positionable between an upright stored position and a horizontal in-use position.

### DETAILED DESCRIPTION

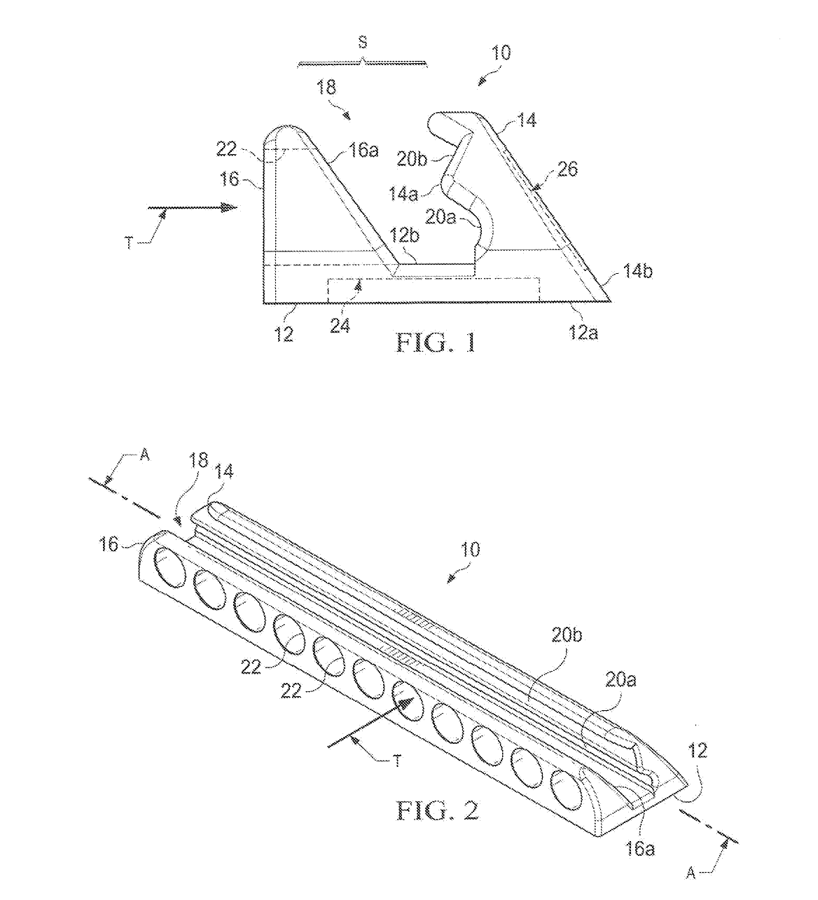

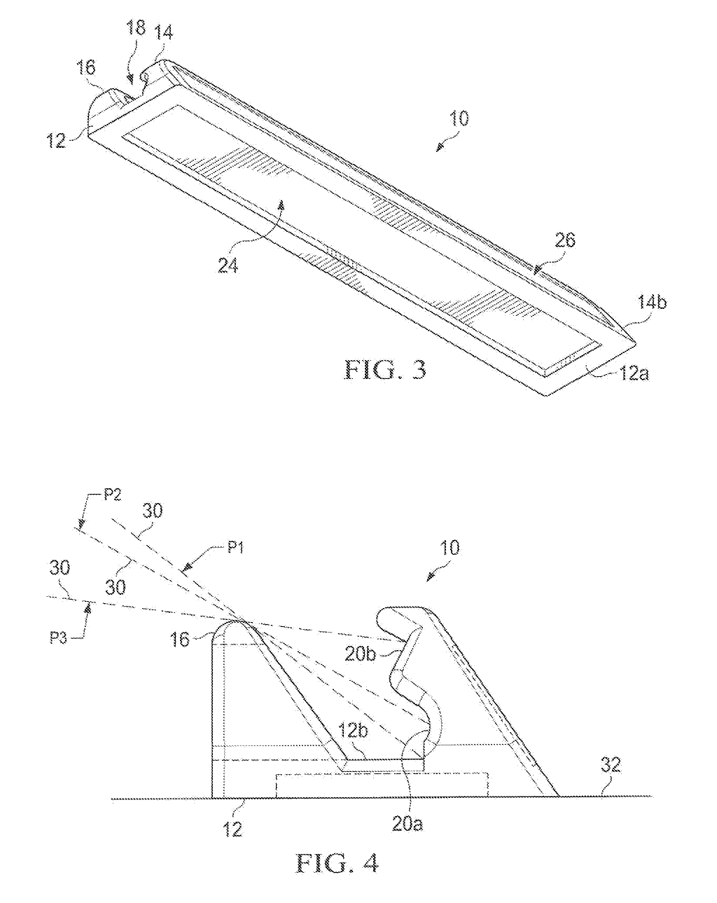

A holder 10 is illustrated in FIG. 1 and includes a base 12, a first wall 14 and an opposite second wall 16 spaced apart by a space S from the first wall 14. The base 12, the first wall 14 and the second wall 16 define an elongated slot or groove 18 extended along an axis A, as illustrated in FIG. 2.

The first wall 14, FIGS. 1 and 2, extends from the base 12. A surface 14a of first wall 14, which is interior to the slot 18, includes a plurality of stacked support lands 20a and 20b. The second wall 16, FIGS. 1 and 2 extends from the base 12 and includes a plurality of apertures 22, opposite the support lands 20a, 20b. The apertures 22 extend through the second wall 16 in a direction designated T which extends transverse to the slot 18.

A surface 16a of second wall 16 is interior to the slot 18 and opposite the surface 14a of first wall 14. Surface 16 is substantially planar.

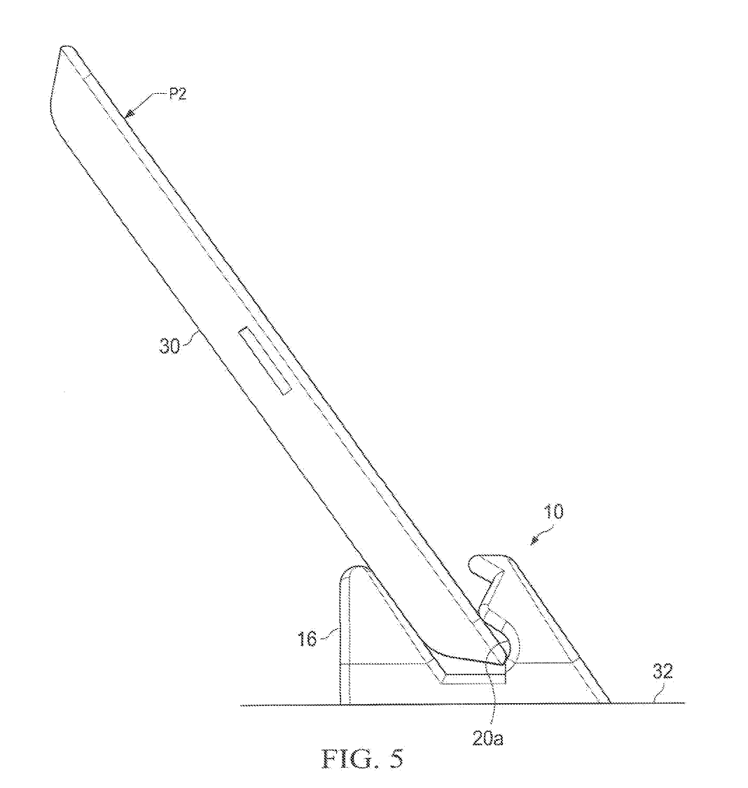

A relief 24, FIGS. 1 and 3, is provided in a surface 12a of base 12 and a relief 26 is provided in a surface 14b of first wall 14. The reliefs 24 and 26 and the apertures 22 provide weight reduction in holder 12 and in addition, the relief 26 and the apertures 22 provide other functions. For example, the relief 26, may receive and retain an inserted strip bearing a logo (not shown) or other such enhancement. An additional function or functions of the apertures 22 will be discussed below in greater detail.

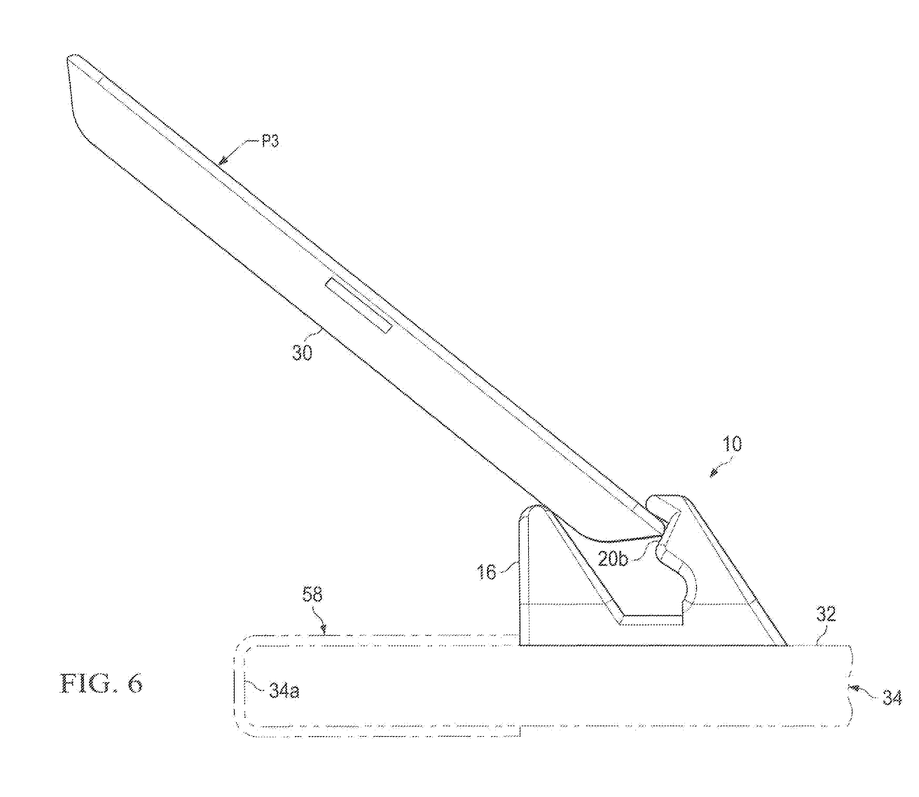

The holder 10 may retain and position a personal electronic device 30 such as a smart phone or a tablet-form electronic device. For example, referring to FIG. 4, FIG. 5 and FIG. 6, such a device 30 may be retained in a first angular position P1 as diagrammatically illustrated in contact with a surface 12b of the base 12 and also in contact with second wall 16. Device 30 may also be retained in a second angular position P2 as diagrammatically illustrated in contact with first land 20a and also in contact with second wall 16. In addition, device 30 may further be retained in a third angular position P3 as diagrammatically illustrated in contact with second land 20b, which is stacked or stepped adjacent land 20a. The device is also in contact with second wall 16. Thus, in this example, three positions are illustrated for selection by a user depending on the desired use of the device 30. For example, in position P1, device 30 may be more suitably used for viewing such as when an entertainment video is being displayed. However, in position P3, the device 30 may be more suitably used interactively at a work angle such as web-surfing or sending emails, for example.

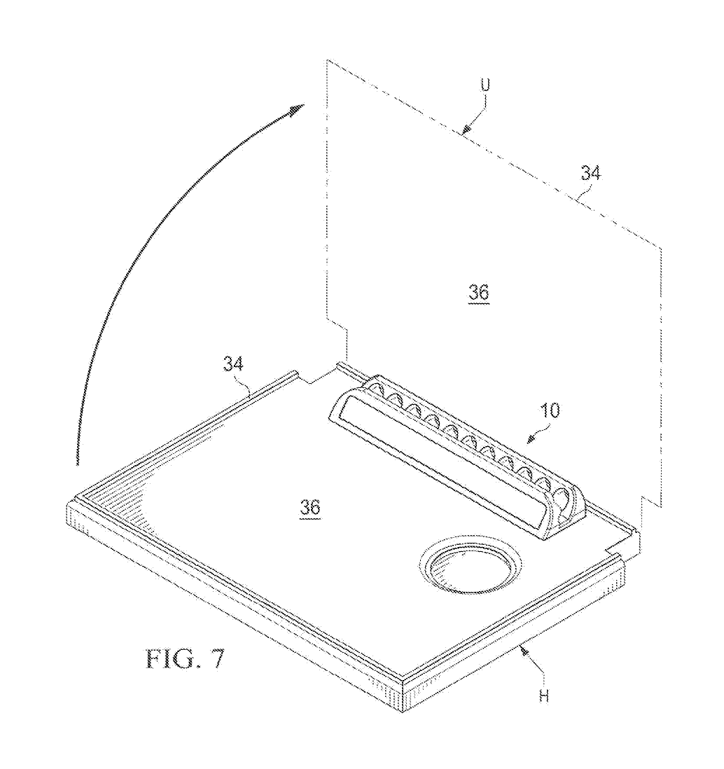

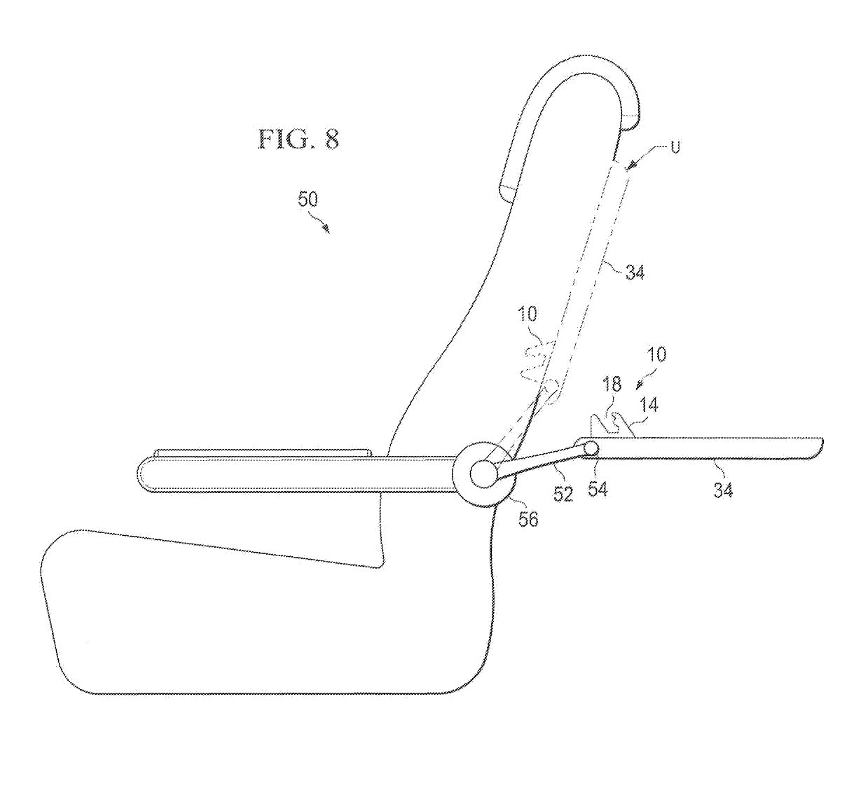

The holder 10 may be supported on a surface 32, FIG. 4, such as a desk or a table and may be used free standing, i.e. not fixed to surface 32, or may be selectively permanently or removably attached to surface 32. Additionally, when used in a travel mode, holder 10 may be supported on a well-known seat-back tray 34 of the type found in a commercial carrier aircraft, see FIGS. 7 and 8. The holder 10 may be either carried by the user and seated or temporarily clamped on the tray 34, or in the alternative, holder 10 may be provided for use as a fixed attachment on a surface 36 of the tray 34 when the tray 34 is in a substantially horizontal position H. However, when the tray 34 is moved to a stored and upright-locked position designated U, the holder 10 is hidden from view.

The holder 10, FIGS. 1-7, may be made by either an injection molding process or by an extrusion process and formed of a suitable synthetic material. The apertures 22 may be machined into the holder 10. The apertures 22 provide several purposes. First, the apertures 22 reduce the weight of the holder 10, provide wire access to an electronic device if needed, and provide a debris escape path when tray 34 is in the stored upright position U.

In FIG. 8, a seat 50 of the type used in commercial aircraft, is illustrated having the seat-back tray 34 supported on the seat 50. A pair of arms 52, only one of which is visible in FIG. 8, interconnects a pivot point 54 on tray 34 with a back portion 56 of the seat 50. The holder 10, see also FIGS. 1 and 7, is shown mounted on the tray 34 and affixed thereto with the groove or slot 18 exposed when the tray 34 is in the horizontal position H. When the tray 34 is moved to the upright position U, the holder 10 is stored against the seat 50.

Advantages of the holder 10 include versatility in that the holder 10 may be used as a portable member and be carried by the user and placed on a support surface including the seat-back tray 34, FIG. 8, when in use. Also, the holder 10 can be attached to the tray 34 by an approved adhesive, or be a molded part of the tray 34. In addition, a clip 58, FIG. 6 may be formed with the holder 10. The clip 58 may be of a U-shape for engagement with an edge 34a of tray 34. In addition, all versions of tablets, readers or smart phones can be supported by the holder 10.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. An apparatus comprising:
a holder including a base, a first wall and an opposite second wall spaced apart from the first wall;
the base, the first wall and the second wall defining an elongated slot;
the first wall extending from the base and having a surface interior to the slot, the surface including a plurality of support lands extending along the slot; and
the second wall extending from the base and including a plurality of apertures opposite the support lands, the apertures extending through the second wall in a direction transverse to the elongated slot.

2. The apparatus of claim 1 wherein the holder is mounted on a support surface.

3. The apparatus of claim 2 wherein the support surface is positionable between a work position and a stored position.

4. The apparatus of claim 3 wherein the holder is fixedly mounted on the support surface.

5. The apparatus of claim 1 wherein the holder is mounted on a tray surface, the tray being positionable between a stored upright position and a substantially horizontal usable position.

6. The apparatus of claim 7 wherein the first and second opposite walls each extend at a substantially similar angle relative to the base, whereby the slot is angularly disposed relative to the base.

7. A multi-positionable support system comprising:
a holder including a base, a first wall and a second wall spaced apart from the first wall;
the base, the first wall and the second wall defining an elongated slot;
the first wall extending from the base and having a surface interior to the slot, the surface including a plurality of support lands extending along the slot;
the second wall extending from the base and including a plurality of apertures opposite the support lands, the apertures extending through the second wall in a direction transverse to the elongated slot;
a personal electronic device selectively mounted in the slot on a first one of the support land and supported at a first angle in response to engagement of the personal electronic device with the second wall; and in response to the personal electronic device being selectively moved to a second one of the support lands, the personal electronic device is being supported in the slot at a second angle, different from the first angle, by engagement with the second wall.

8. The system of claim 7 wherein the holder is mounted on a tray surface, the tray being positionable between a stored upright position and a substantially horizontal position.

9. The system of claim 8, further comprising:
a first relief formed in the first wall, a second relief formed in the base, and the plurality of apertures providing means for reducing weight of the holder, for providing wire access to the personal electronic device, and for providing a debris escape path in response to the tray being positioned in the stored upright position.

10. The system of claim 7 wherein the first and second opposite walls each extend at a substantially similar angle relative to the base, whereby the slot is angularly disposed relative to the base.

11. The apparatus of claim 7 wherein the holder is mounted on a support surface.

12. The apparatus of claim 11 wherein the support surface is positionable between a work position and a stored position.

13. The apparatus of claim 12 wherein the holder is fixedly mounted on the support surface.

14. The apparatus of claim 8, further including:
a clip attached to the holder and the clip being engaged with an edge portion of the tray.

15. In combination with a passenger seat on a commercial carrier, the seat comprising:
a back surface of the seat;
a tray mounted on the back surface, the tray being movable between an upright and stored position and a substantially horizontal in-use position;
a holder supported on the tray, the holder including a base, a first wall and an opposite second wall spaced apart from the first wall, the base and the first and second walls defining an elongated slot;
the first wall extending from the base and having a surface interior to the slot and including a plurality of elongated support lands extending along the slot; and
the second wall extending from the base and including a plurality of apertures opposite the support lands; the apertures extending through the second wall in a direction transverse to the elongated slot.

16. The combination of claim 15 wherein the holder is fixedly mounted on the tray.

17. The combination of claim 15, further including:
a clip attached to the holder, the clip being engaged with an edge of the tray.

18. The combination of claim 15 wherein the first and second opposite walls each extend at a substantially similar angle relative to the base, whereby the slot is angularly disposed relative to the base.

19. The combination of claim 15, further comprising:
a first relief formed in the first wall, a second relief formed in the base, and the plurality of apertures providing means for reducing weight of the holder, for providing wire access to the personal electronic device, and for providing a debris escape path in response to the tray being positioned in the stored upright position.

20. The combination of claim 15, further comprising:
a personal electronic device selectively mounted in the slot on a first one of the support lands and supported at a first angle in response to engagement of the personal electronic device with the second wall, and in response to the personal electronic device being selectively moved to a second one of the support lands, the personal electronic device being supported in the slot at a second angle, different from the first angle by engagement with the second wall.
